(19) United States
(12) Patent Application Publication
(10) Pub. No.: US 2016/0087131 A1
(43) Pub. Date: Mar. 24, 2016

(54) FACADE ELEMENT OR ROOF ELEMENT

(71) Applicant: BS2 AG, Schlieren (CH)

(72) Inventor: Marc BAETSCHMANN, Zürich (CH)

(21) Appl. No.: 14/785,496

(22) PCT Filed: Apr. 3, 2014
(86) PCT No.: PCT/EP2014/056731

§ 371 Date: Oct. 19, 2015

(30) Foreign Application Priority Data
Apr. 18, 2013 (CH) 792/13

(51) Int. Cl. H01L 31/052; H02S 20/25

(52) U.S. Cl. CPC H01L 31/052; H02S 20/25

(57) ABSTRACT

A façade element or roof element (1) has one or more photovoltaic solar cells (31, 32, 33) which are connected to one or more heat-conducting layers (5) in a heat-conducting manner, and at least one heat insulation element (3) which is arranged on the surface of the heat-conducting layers remote from the solar cells.

The present invention relates to a façade element or roof element according to the preamble of claim 1, as well as to a roof construction or façade construction with at least one façade element or roof element.

Solar radiation is a form of energy that appears predominantly in the frequency range of comparatively short wavelengths of less than 2 micrometers wavelength on the surface of the earth. The energy of the solar radiation can be converted partially into electrical current or partially into thermal energy, too. In both processes of energy conversion the energy of the photons of the solar radiation is partially absorbed by a solid body. In the photovoltaic cell an as large as possible fraction of the energy of the photons is directly converted into a flow of electrical energy.

The fraction of absorbed radiation energy cannot be converted into electrical energy with 100% efficiency. The remainder is converted into thermal energy, which has to be lead away from the photovoltaic cell, in order to maintain its performance. Since the photovoltaic effect depends on the temperature of the absorbing layer (higher temperatures reduce the electrical efficiency), the heat needs to be carried away from the photovoltaic cell at relatively low temperature.

The photovoltaic layer is very thin and needs to be fixed mechanically at or on a support plate for reasons of stability, the support plate absorbing the various forces acting on the surface and transferring them to a support structure that for its part is firmly connected to the earth. The element consisting of the photovoltaic layer and the force transferring support plate is referred to as solar panel.

A trend in photovoltaics is the building integration, the combination of function of the building envelope and the current producing photovoltaic modules. Thereby the photovoltaic module replaces the outermost building envelope, e.g. the tile. The photovoltaic module is fixed directly onto the roof substructure by means of a mounting system, e.g. hooks.

In today's building integration the decreasing efficiency of higher module temperatures is counteracted by means of natural or forced rear ventilation of the modules. In roof construction structures with a spacing between modules and insulation are used that allows cooling by means of natural convection. Not in all cases a reliable cooling is achieved in satisfactory manner. That way, in building integrated installations besides a higher load onto the modules often a reduced electrical yield can be observed. An active cooling is rarely applied with pure photovoltaics. There exist so called “hybrid systems” with active air cooling of the back side of the module using forced convection over the whole roof area. Or recently known hybrid collectors, the cooling of which is limited to single modules.

Existing systems or known systems, respectively, for exploitation of the heat to be carried away from the photovoltaic cells usually aim to remove the heat at temperatures as high as possible and on a surface a large as possible on the absorbing layer. This way, costly panel constructions result. Systems of this kind are for example known from WO 2009/149572, DE 20 2007 010 901, DE 20 2007 000529, EP 1 914 489 as well as from DE 20 2007 009 162. Furthermore the JP 10062017 describes a photovoltaic, current producing and heat producing hybrid panel used as covering module, wherein the heat collector arranged behind the photovoltaic cell shows an air cooling at the back side of the module. Similar modules are described in WO 2012/155850 and in WO 2011/014120, whereby also here an air cooling is provided at the back side of the module.

The object of the present invention consists on the one hand in being able to carry away and use the heat forming in photovoltaic solar cells and on the other hand in creating so-called hybrid solar modules that are integratable by minimal engineering effort into building constructions such as roofs and façade.

According to the invention a façade element or roof element according to the wording of claim 1 is proposed.

The idea according to the invention consists in a combination of function of building envelope, photovoltaics, thermal absorber and newly of the thermal insulation of the building, hence a complete roof element or façade element with integrated production of electrical as well as thermal energy and at the same time insulation of the building envelope.

According to the invention it is proposed that the façade element or roof element comprises in addition to one or more photovoltaic solar cells at least a heat-conducting layer, as a heat transfer plate, connected to the solar cell or cells in a heat-conductive manner, which heat-conducting layer preferably is connected to a large extent in a flat manner with the solar panel. At the surface of the heat-conducting layer opposite to the solar cell a heat insulation element is arranged, whereby the insulation of the building is—contrary to the usually known so-called hybrid collectors—integrally included in the façade element or roof element.

Further it is proposed that in or on the heat-conducting layers means are provided for supplying heat into or removing heat from the heat-conducting layer, such as for example a heat transfer medium that is guided in a pipe arrangement for heat transfer.

Again, according to a further embodiment it is proposed that the heat-conducting layer mechanically fixes the photovoltaic layer for stability reasons, such as the heat transfer plate being at the same time support plate, wherein for example several heat-conducting layers in the form of segments may be provided, which are spaced from each other where appropriate.

Again, according to an embodiment it is provided that in the heat insulation element or in the heat insulation layer, respectively, grooves or channels can be provided at the surface facing to the heat-conducting layer for drainage, dehumidification and/or venting of the roof element or façade element, or that the heat insulation layer and the heat-conducting layer for this purpose for the creation of interspaces are at least partially spaced from each other.

Again, according to a further embodiment it is provided that the heat-conducting layer itself or the segments building up the heat-conducting layer, such as e.g. lamellae, show at least one stepping each. This way it becomes possibly that, when using several solar cells per element, these solar cells can be arranged along a connecting edge of two neighboring solar cells in the area of the stepping in a partially overlapping way, corresponding to the arrangement of cover plates of a roof construction.

If now in addition to the building integration of the photovoltaics a functional integration with the thermal insulation is established, a controlled cooling of the photovoltaic cells is advantageous. By means of an absorber, through which for example liquid is flowing and which is attached to the backside of the solar cells, the heat can be carried away at any time in large amounts. This increases the longevity of the modules as well as the electrical efficiency. The additional electrical yield of a PV module cooled by means of a thermal absorber and rear-ventilated amounts in comparison to a not cooled, rear-ventilated PV module approx. 4 to 5%. When comparing a not rear-ventilated, cooled PV module to a likewise not rear-ventilated and not cooled PV module, the difference increases up to 10%.

The additional building insulation, which is integrated according to the invention, at the same time acts as thermal insulation on the back side of a hybrid collector. Thereby, in comparison to not insulated collectors, an additional thermal yield of annually 12-15% is achieved. If the insulation of the collector is combined with the insulation of the building envelope, this additional yield can be achieved without additional use of material and grey energy.

Newly, hybridization occurs not any more separately per module but involves several modules or solar cells, respectively. The fluid carrying heat-conducting plate, for example made of aluminum, is part of the whole element and at the same time is used as static structure. On the one hand it serves as static support element of the photovoltaic solar cells and on the other hand it acts as mounting system of the photovoltaic modules on the roof. The hybridization combines the thermal absorber with the supporting structure and forms a coolable roof construction. The roof, e.g. made of aluminum, may already form a completely watertight construction.

The hydraulic connectors may be arranged at the edge of the element and may be interconnected among each other as well in series as in parallel. In comparison to the hybridized known single modules these connectors are easily accessible and e.g. visually checkable. The absorber is constructionally formed such that it enables an arrangement of the photovoltaic modules as a consequence of the removable fixing, such that they can accomplish their function as water-repellent building envelope. In addition it is possible to remove each photovoltaic module individually from the construction and replace it e.g. in case of defect. For this purpose the hydraulical circuit is not interrupted and therefore the system needs not to be emptied, be refilled and be vented. Solely the electrical circuit has to be interrupted and the module has to be replaced.

The supporting structure can as well be covered with different covering material than electrically active photovoltaic modules. E.g. dummy modules (electrically inoperable), glass plates, eternit plates, etc.

The functional combination of functions of energy production with the building envelope (water carrying layer, fire protection, etc.) allows a reduction of the number of layers of a roof composition.

Vertical water drain channels may be integrated into the support profile or be installed as separate element between the modules. Due to the dilatation in length of the modules, they can be installed in an overlapping way or with a spacing, respectively.

The statical requirements of the photovoltaic module are additionally taken over by the support structure, which enables to build the photovoltaic modules themselves with a reduced inherent stability, which leads to materials savings and consequently cost reductions for the photovoltaic modules.

The system can be used for roofs as well as for facades. The whole element is realized in such a way that it can be prefabricated easily and can be transported to the construction site as complete roof element and can be moved there. A possible exemplary prefabrication of such large area roof elements additionally simplifies the planning process as well as the installation process. The element and its connections can be checked already in the production hall. Besides the smaller number of connections and the corresponding smaller statistical risk of a defect, this way a large fraction of the quality insurance is shifted from the construction site to the production hall. It is of course possible as well, to transfer the photovoltaic modules only at the construction site onto the prefabricated support structure.

Decisive advantages of the novel system building element thus are cost and material savings of the roof as well as of the individual components. In addition, a simpler, faster and safer planning process and installation process. Thus, a reduction of the total system cost is achieved. This construction leads to a new architecture of roofs, thus besides the technical and economical advantages the building integration of hybrid collectors is desirable out of reasons based in building regulations.

A further advantage of such a roof element is a smaller heat input through the roof into the building in case of high solar irradiation. This increases the comfort level, in particular in developed attic floors, because the heat can be carried away from the roof element in a controlled way. The invention is now explained in more detail by way of example and by reference to the attached figures.

Thereby show:

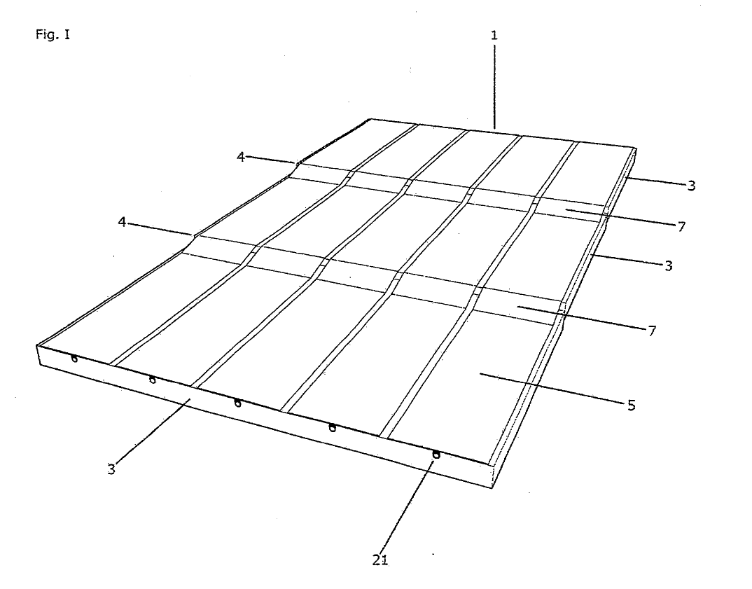

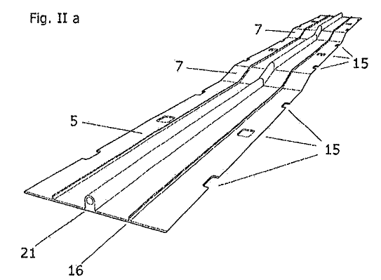

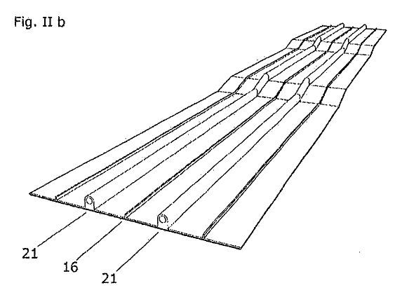

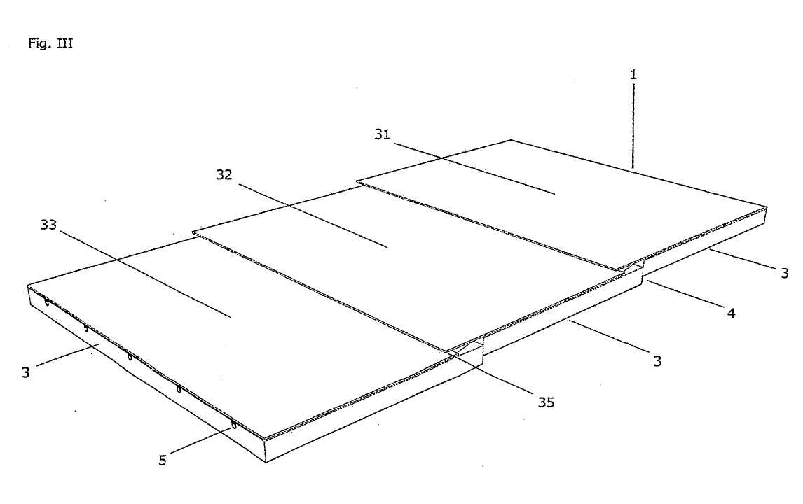

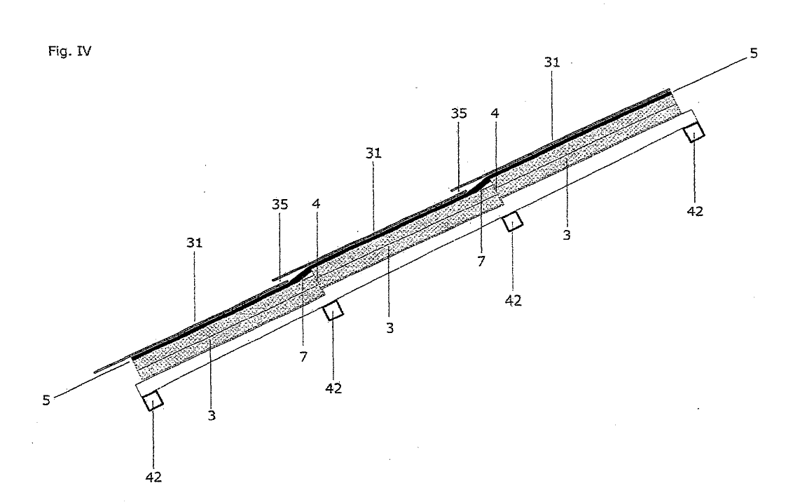

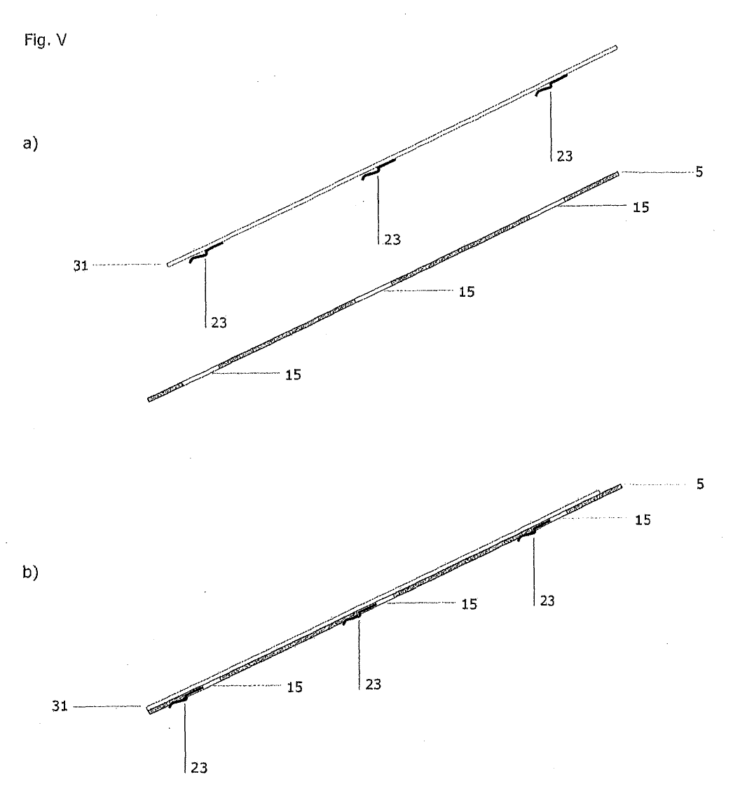

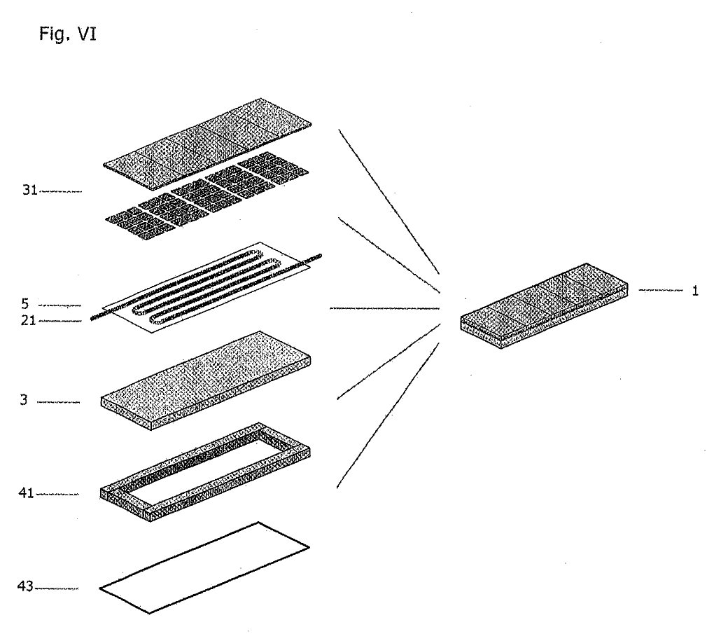

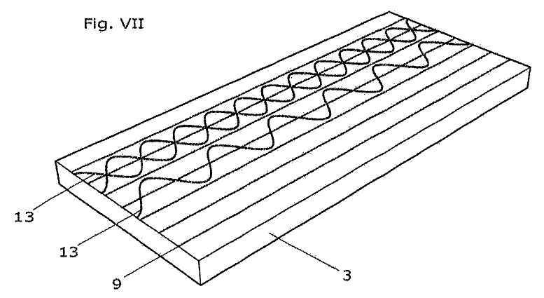

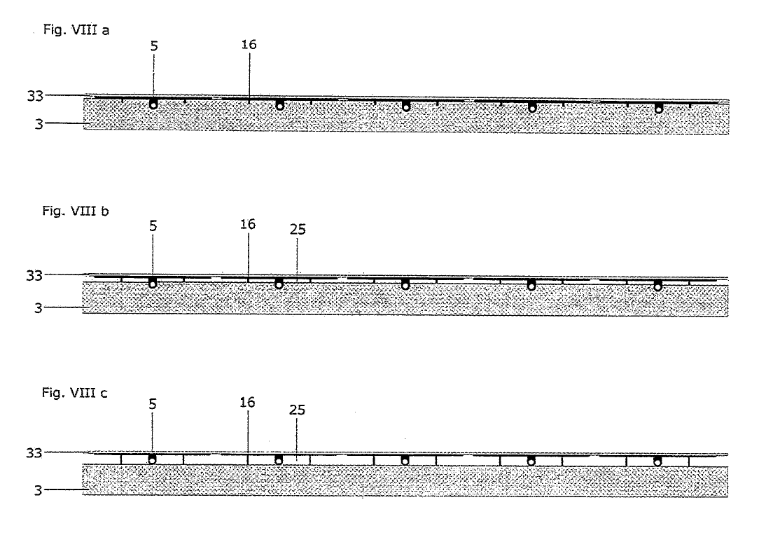

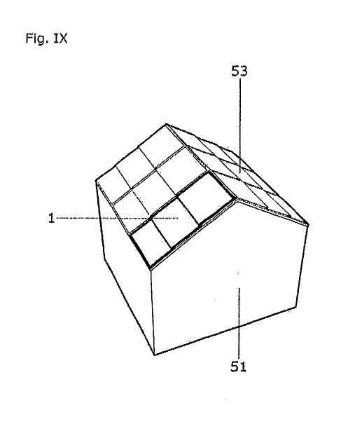

FIG. 1 in perspective top view a fluid cooled support structure of lamella-type along with the heat insulation element arranged behind it,

FIGS. 2a and 2b individual lamellae of the support layer for fixing the solar cells in perspective view,

FIG. 3 in perspective top view a roof element according to the invention making use of the supporting lamellae and the heat insulation layer from FIG. 1,

FIG. 4 a cross section through a roof construction making use of roof elements according to the invention,

FIG. 5 in cross-sectional view a solar cell mounted to a lamella of the heat-conducting support layer and

FIG. 6 schematically the assembling and arrangement of the different modules and layers to a roof element according to the invention

FIG. 7 different variants of grooves and channels in the heat insulation layer for creation of a clearance

FIG. 8a-c different design variants of the clearance between heat insulation layer and support lamella FIG. 9 the arrangement of several roof elements on a roof of a house.

FIG. 1 shows in perspective top view the construction of a roof panel 1 according to the invention without the solar cell to be placed on top of it. On a heat insulation layer 3, for example consisting of thermally insulating material of known kind, well heat-conducting, for example lamella-like, metal profiles 5, for example consisting of aluminum, are provided. Of course it is possible, to design the heat-conducting layer or the supporting layer for the solar cells as one piece or to design the individual segments differently, such as trapezoidal, triangular, in form of a rhomb, etc. However, the lamella-like design seems to be advantageous from a manufacturing point of view, mechanical and thermal advantages result as well. Well recognizable is a stepping 7 in the depicted lamellae 5, the function of which will be discussed later, in particular with reference to both of the FIGS. 3 and 4. Corresponding to the steppings 7 a step 4 is provided in the heat insulation layer 3 arranged below, too. Heat-conducting with the metallic lamellae 5 pipes 21 are provided that are integrally connected to the heat-conducting plates to carry a fluidic heat transport medium. Obviously, the individual lamellae can be arranged in a position rotated by 90% respective to the illustration, whereby the stepping, too, obtains a different position.

FIG. 2a shows in perspective view an individual metal lamella or support lamella 5, respectively, seen from below, together with the conduit pipe 21 integrally connected with it. Further well recognizable is the stepping 7. A metal lamella of this kind, for example consisting of aluminum can be produced by means of strand extrusion. Instead of metal of course a heat-conducting polymer e.g. a filled polymer can be used.

Finally perforations 15 provided for the pluggable fixation of solar cells are recognizable in the metal lamellae 5. FIG. 2b shows a further possible embodiment of the metal lamella or support lamella 5, respectively, with integrated spacer 16.

In FIG. 3 analogous to the view of FIG. 1 again a roof element 1 according to the invention is displayed in perspective top view. In addition to the elements displayed in FIG. 1, in FIG. 3 three solar cells 31, 32 and 33 are arranged that are firmly attached to the heat-conducting support profiles or support lamellae 5, respectively. In the area of the stepping 7 of the support lamellae or metal lamellae 5 or the step 4 of the heat insulation element 3, respectively, the solar cells 31 and 37 for example overlap over a distance 35. This overlap of the solar cells in the roof element 1 corresponds to the overlap of roof cover plates as for example tiles, eternit plates, etc. in order to ensure a drainage of for example rain water. In order to still be able to drain off rain water possibly entering in the overlap region into the element lying below, longitudinal channels provided in the heat insulation layer 3 are responsible. Instead of the channels it is possible, that, by means of the conduit pipes extending e.g. from the heat conducting plate downward, interspaces 41 are formed between heat-conducting layer and heat insulation layer, through which a drainage of water or a venting is ensured. This is displayed by way of example in the FIGS. 8a-c. Due to the relatively large area of solar cells it is now important, too, that these are firmly attached to the heat-conducting support lamellae 5 lying below, in order to be able to counteract to the occurring forces for example in case of extreme wind conditions. On the one hand it is possible to hold the solar cells in the perforations 15 in the lamella-like metal support plates by means of for example hooks. Other fastening systems for secure fixing of solar cells on support plates are for example known from WO 2011/076456, which hereby are integral part of the present invention, too.

FIG. 4 shows in cross-sectional view a roof construction with a roof element according to the invention showing several solar cells 31 that are fixed to the support layer 5 arranged below, overlapping each other on their upper and lower edge. The displayed support layer or heat-conducting lamella 5, respectively, shows two steppings 7 in the case of the embodiment displayed, and in the thermally insulating layer 3 laying below corresponding steps 4 are formed, as well. Finally, integrally connected with the supporting lamella 5 is a tube 21 for conducting the heat transfer medium.

FIG. 5 shows a possible fixation of the solar cell 31 on the heat-conducting layer or support lamella 5, respectively, in the area of the openings 15. By means of e.g. clamp-like elastic hooks 21, which are attached to the solar cell 31, these are arranged fixedly in a way reaching behind the lamella in the area of the opening 15. By shifting in direction of the arrow A the individual solar cell 31 can be removed, whereby an individual exchange of a solar cell in a roof or façade element is enabled. Of course other systems of fixation are possible.

On the basis of FIG. 6 finally shall be displayed schematically, how a roof element according to the invention is built up in order to be arranged on a roof 53 of a building 51, which is displayed in FIG. 9. The solar cell 31 consisting of glass cover and photovoltaic electro structure is arranged on a for example metallic support plate 5 comprising a tube arrangement 21 for conducting the heat transfer medium. The heat-conducting plate 5 for their part is arranged on a heat insulation element 3 and firmly connected to this heat insulation element. Finally, a usually with roof constructions provided for example wooden construction 41 is provided having for example a wooden cover 43 on the interior side of the room. The element 1 designed this way can be prefabricated and arranged on a building 51 under construction. Of course, depending on the size, several roof elements can be arranged on a roof in direction of roof inclination, as well. The size and the form of the roof element on the one hand depends on the roof construction, the transportability of the elements, etc., or the size or geometry of the roof to be covered. Thus, the elements can be trapezoidal, triangular or rhomboid, etc.

In FIG. 7 channels or grooves 9 for example running in direction of the lamellae, as well as a structure of channels 13, which for example can be designed in form of a sinus curve are recognizable in the heat insulation layer 3. These grooves and channels are provided in particular to drain for example rain water penetrating through the roof construction, humidity occurring in the roof element or generally to vent the roof element. In particular the grooves 9 guided between the metal lamellae are provided for drainage.

In FIG. 8a-c by way of examples different forms of the interspace 41 are displayed.

FIG. 8a shows a complete integration of the absorber into the heat insulation layer.

FIG. 8b shows the partial integration of the lamella into the heat insulation layer with formation of the interspace 41 by a spacer that in this case is integrated in the form of the lamella.

FIG. 8c shows the design of the interspaces with the gap, which results from the positioning of the lamella onto the planar heat insulation layer.

Analogously to the displayed roof construction it is of course possible as well to create similar façade elements and to arrange them on a façade of a house.

The roof elements shown in the FIGS. 1 to 9 are of course only examples for better explanation of the present invention. Thus, it is possible to arrange one or more solar cells per roof element, to design the heat-conducting support layer arranged below in one piece or by means of several lamellae and one or more steppings can be provided in the individual lamellae, too. The heat insulation element situated below can be designed differently, too, and needs not mandatory to be designed to be fixedly attached to the heat-conducting support layer. The material used for the heat insulation element is not part of the present invention and the widest variety of materials can be used for this purpose. It is advantageous, that in the roof element proposed according to the present invention further functional elements can be integrated, such as fire protection, soundproofing, etc.

Essential for the invention is, that in the roof element or façade element, respectively, according to the invention the photovoltaic solar module or the cells, respectively, the support layer being in a heat-conducting manner connected with it and newly the heat insulation element arranged at the surface opposite to the solar module are assembled to a single unit.

1. Façade element or roof element having at least one photovoltaic solar cell, comprising at least one heat-conducting layer connected to the at least one solar cell in a heat-conducting manner and at least one heat insulation element arranged on the surface of the at least one heat-conducting layer opposite to the at least one solar cell.

2. Façade element or roof element according to claim 1, further comprising means for supplying heat into or removing heat from the at least one heat-conducting layer, the means for supplying heat or removing heat being arranged in or on the at least one heat-conducting layer.

3. Façade element or roof element according to claim 1, wherein the at least one heat-conducting layer is formed by several segments, which are spaced from each other where appropriate.

4. Façade element or roof element according to claim 3, wherein in the al least one heat-conducting layer or in the segments of the at least one heat-conducting layer one or more steppings are provided.

5. Façade element or roof element according to claim 1, wherein the at least one heat insulation element has at least one of channels, grooves and interspaces provided between the at least one heat-conducting layer and the at least one heat insulation layer for at least one of draining of water, dehumidification and venting of the element.

6. Façade element or roof element according to claim 1, wherein the at least one solar cell is detachably connected to the heat-conducting layer.

7. Façade element or roof element according to claim 1, wherein a plurality of solar cells are provided arranged overlapping each other along a joining edge of two neighboring cells.

8. Façade element or roof element according to claim 7, wherein the overlap of the solar cells is provided in the area of steppings in the at least one heat-conducting layer or segments of the at least one heat-conducting layer.

9. Façade element or roof element according to claim 2, wherein the means for supplying heat or removing heat is a viscous or liquid, respectively, heat transport medium, guided in a tube arrangement, which is connected to the at least one heat-conducting layer or a lamellae of the at least one heat-conducting layer, respectively, in a heat-conducting manner.

10. Façade element or roof element according to claim 3, wherein the segments forming the at least one heat-conducting layer are lamellae being at least nearly parallel side by side spaced from each other.

11. Façade element or roof element according to claim 1, wherein the at least one heat-conducting layer is at the same time a support plate for the at least one solar cell, in order to attach the solar cell to the element as well as to secure the element statically.

12. Roof construction or façade construction comprising several roof elements or façade elements according to claim 1.
